(19) United States
(12) Patent Application Publication
(10) Pub. No.: US 2023/0145264 A1
(43) Pub. Date: May 11, 2023

(54) PHOTOSENSITIVE RESIN COMPOSITION, PHOTOSENSITIVE ELEMENT, AND METHOD FOR PRODUCING WIRING BOARD

(71) Applicant: Showa Denko Materials Co., Ltd., Tokyo (JP)

(72) Inventors: Keishi ONO, Tokyo (JP); Seiji SUNOHARA, Tokyo (JP); Tetsuro YAMASHITA, Tokyo (JP); Yuya HIRAYAMA, Tokyo (JP)

(21) Appl. No.: 17/913,016

(22) PCT Filed: Mar. 16, 2021
(86) PCT No.: PCT/JP2021/010588

§ 371 Date: Sep. 20, 2022

(30) Foreign Application Priority Data
Mar. 24, 2020 (JP) PCT/JP2020/013106

(51) Int. Cl. G03F 7/031; G03F 7/033; C08F 212/08; C08F 220/18; H05K 3/10

(52) U.S. Cl. CPC G03F 7/031; G03F 7/033; C08F 212/08; C08F 220/1807; H05K 3/10

(57) ABSTRACT

A photosensitive resin composition containing a binder polymer, a photopolymerizable compound, a photopolymerization initiator, and an anthracene-based sensitizer, in which the binder polymer contains a polymer (a) having a hydroxyalkyl (meth)acrylate unit and a styrene or styrene derivative unit and having a content of the styrene or styrene derivative unit of 40% by mass or more.

### TECHNICAL FIELD

The present disclosure relates to a photosensitive resin composition, a photosensitive element, and a method for producing a wiring board.

### BACKGROUND ART

In the production of wiring boards, resist patterns are formed in order to obtain desired wirings. In the formation of resist patterns, a photosensitive resin composition has been widely used. In recent years, with decreasing sizes and increasing densities of electronic devices, formation of finer wirings than conventional cases has been required also in wiring boards. MSAP (Modified Semi Additive Process) and SAP (Semi Additive Process) have been drawing attentions as a method for producing a wiring board with which such a demand is achieved. In these methods, in order to form a fine wiring, for example, formation of a resist pattern with 7 μm or less as an index for adhesiveness and 12 μm or less as an index for resolution is required.

Hitherto, improvement of the photosensitive resin composition by addition of a photosensitizer has been carried out in order to improve resolution and adhesiveness of a resist pattern to be formed. As the photo sensitizer, for example, an anthracene derivative such as 9,10-dibutoxyanthracene (DBA) has been studied (see, for example, Patent Literature 1).

### CITATION LIST

### Patent Literature

Patent Literature 1: International Publication WO 2007/004619

### SUMMARY OF INVENTION

### Technical Problem

However, in the photosensitive resin composition containing DBA described in Patent Literature 1, formation of a resist pattern with 7 μm or less as an index for adhesiveness and 12 μm or less as an index for resolution cannot be achieved, and it is required for the photosensitive resin composition to improve adhesiveness and resolution of a resist pattern to be obtainable.

Therefore, an object of the present disclosure is to provide a photosensitive resin composition and a photosensitive element with which a resist pattern superior in adhesiveness and resolution can be formed, and a method for producing a wiring board by using these photosensitive resin composition and photosensitive element.

### Solution to Problem

In order to achieve the above-described object, the present disclosure provides a photosensitive resin composition containing: a binder polymer; a photopolymerizable compound; a photopolymerization initiator; and an anthracene-based sensitizer, in which the binder polymer contains a polymer (a) having a hydroxyalkyl (meth)acrylate unit and a styrene or styrene derivative unit and having a content of the styrene or styrene derivative unit of 40% by mass or more.

According to the photosensitive resin composition, by using the specific polymer (a) in combination with the anthracene-based sensitizer, a resist pattern superior in adhesiveness and resolution can be formed. The reason for this is conceivable that, when the polymer (a) contains the hydroxyalkyl (meth)acrylate unit and contains 40% by mass or more of the styrene or styrene derivative unit, water absorbability of the polymer (a) and dispersibility of the polymer (a) in the photosensitive resin composition are improved, and when this polymer (a) is used in combination with the anthracene-based sensitizer, high developability and high adhesiveness can be exhibited.

In the photosensitive resin composition, the photopolymerizable compound may contain a polyfunctional monomer having two or more reactive groups reacting with radicals and having 2 to 40 of oxyethylene groups and/or oxypropylene groups in total. By containing the above-described polyfunctional monomer, the alkali resistance of a resist pattern to be obtainable can be further improved, and more superior adhesiveness can be obtained.

In the photosensitive resin composition, the photopolymerizable compound may contain 2,2-bis(4-((meth)acryloxypolyethoxy)phenyl)propane in which the number of oxyethylene groups is 10 or more. By containing the above-described compound, adhesiveness and resolution of a resist pattern to be obtainable can be further improved.

In the photosensitive resin composition, the photopolymerizable compound may contain 2,2-bis(4-((meth)acryloxypolyethoxy)phenyl)propane in which the number of oxyethylene groups is less than 10. By containing the above-described compound, adhesiveness can be further improved. When the number of oxyethylene groups is set to be less than 10, the molecular weight between crosslinking points of an exposed area is decreased, swelling of the exposed area with respect to a developing solution is suppressed, and adhesiveness is improved.

In the photosensitive resin composition, the photopolymerizable compound may contain 2,2-bis(4-((meth)acryloxypolyethoxy)phenyl)propane in which the number of oxyethylene groups is 10 or more and 2,2-bis(4-((meth)acryloxypolyethoxy)phenyl)propane in which the number of oxyethylene groups is less than 10.

In the photosensitive resin composition, a weight average molecular weight of the polymer (a) may be 30000 to 40000. By using this polymer (a), dispersibility of the polymer (a) in the photosensitive resin composition is further improved, and more superior high developability and high adhesiveness can be realized.

In the photosensitive resin composition, a content of the anthracene-based sensitizer may be 0.2 parts by mass or more and less than 0.8 parts by mass with respect to 100 parts by mass of the total amount of the binder polymer and the photopolymerizable compound. When the content of the anthracene-based sensitizer is within the above range, more superior high developability and high adhesiveness can be realized, and a resist pattern shape can be formed more favorably. Further, when the content of the anthracene-based sensitizer is less than 0.8 parts by mass, it is possible to suppress the anthracene-based sensitizer from being precipitated on the surface of the photosensitive resin layer formed using the photosensitive resin composition when a photosensitive element is formed and stored in a refrigerator.

The present disclosure further provides a photosensitive element including: a support; and a photosensitive resin layer formed using the above-described photosensitive resin composition of the present disclosure on the support.

The present disclosure further provides a method for producing a wiring board, the method including: a step of providing a photosensitive resin layer on a substrate by using the above-described photosensitive resin composition of the present disclosure or the above-described photosensitive element of the present disclosure; a step of photo-curing a part of the photosensitive resin layer; a step of removing an uncured area of the photosensitive resin layer to form a resist pattern; and a step of forming a wiring layer on a part of the substrate in which the resist pattern is not formed.

### Advantageous Effects of Invention

According to the present disclosure, it is possible to provide a photosensitive resin composition and a photosensitive element with which a resist pattern superior in adhesiveness and resolution can be formed, and a method for producing a wiring board by using these photosensitive resin composition and photosensitive element.

### BRIEF DESCRIPTION OF DRAWINGS

FIG. 1 is a schematic cross-sectional view illustrating a photosensitive element according to an embodiment.

FIG. 2 is a schematic view illustrating a method for producing a wiring board according to an embodiment.

### DESCRIPTION OF EMBODIMENTS

Hereinafter, embodiments of the present disclosure will be described in detail.

In the present specification, the term “step” includes not only an independent step but also a step by which an intended action of the step is achieved, even though the step cannot be clearly distinguished from other steps. A numerical range that has been indicated by use of “to” indicates the range that includes the numerical values which are described before and after “to,” as the minimum value and the maximum value, respectively. The term “layer” includes a structure having a shape which is formed on a part, in addition to a structure having a shape which is formed on the whole surface, when the layer has been observed as a plan view. The term “(meth)acrylic acid” means at least one of “acrylic acid” and “methacrylic acid” corresponding thereto. The same applies to other analogous expressions such as (meth)acrylate.

In the present specification, the term “(poly)oxyethylene group” means an oxyethylene group or a polyoxyethylene group in which two or more ethylene groups are linked via an ether bond. The term “(poly)oxypropylene group” means an oxypropylene group or a polyoxypropylene group in which two or more propylene groups are linked via an ether bond. The term “EO-modified” compound means a compound having a (poly)oxyethylene group. The term “PO-modified” compound means a compound having a (poly)oxypropylene group. The term “EO, PO-modified” compound means a compound having a (poly)oxyethylene group and/or a (poly)oxypropylene group.

In the present specification, when a plurality of substances corresponding to each component exist in the composition, the amount of each component in the composition means the total amount of the plurality of substances that exist in the composition, unless otherwise specified. In the present specification, the term “solid content” refers to a non-volatile content of a photosensitive resin composition excluding volatile substances (such as water and a solvent). That is, the term “solid content” refers to components except a solvent, remaining without volatile in drying of the photosensitive resin composition described below and including components present in a liquid, syrupy and waxy state at room temperature (25° C.).

<Photosensitive Resin Composition>

A photosensitive resin composition according to the present embodiment contains a component (A): a binder polymer, a component (B): a photopolymerizable compound, a component (C): a photopolymerization initiator, and a component (D): an anthracene-based sensitizer. Here, the component (A) contains a polymer (a) having a hydroxyalkyl (meth)acrylate unit and a styrene or styrene derivative unit and having a content of the styrene or styrene derivative unit of 40% by mass or more. Furthermore, the photosensitive resin composition according to the present embodiment may further contain a component (E): a polymerization inhibitor. Hereinafter, respective components will be described.

Component (A): Binder Polymer

The photosensitive resin composition contains one or two or more kinds of the components (A). Examples of the component (A) include an acrylic resin, a styrene-based resin, an epoxy-based resin, an amide-based resin, an amide/epoxy-based resin, an alkyd-based resin, and a phenol-based resin. From the viewpoint of further improving alkali developability, the component (A) may contain an acrylic resin. The photosensitive resin composition according to the present embodiment contains, as the component (A), at least a polymer (a) having a hydroxyalkyl (meth)acrylate unit and a styrene or styrene derivative unit and having a content of the styrene or styrene derivative unit of 40% by mass or more.

The polymer (a) has a hydroxyalkyl (meth)acrylate unit (a structure unit derived from hydroxyalkyl (meth)acrylate). The hydroxyalkyl (meth)acrylate may be, for example, hydroxymethyl (meth)acrylate, hydroxyethyl (meth)acrylate, hydroxypropyl (meth)acrylate, hydroxybutyl (meth)acrylate, hydroxypentyl (meth)acrylate, hydroxyhexyl (meth)acrylate, and the like. Furthermore, in a case where the number of carbon atoms of the alkyl moiety in the hydroxyalkyl (meth)acrylate unit is 3 or more, the polymer (a) may have a branched structure.

The content of the hydroxyalkyl (meth)acrylate unit in the polymer (a) may be 0.5% by mass or more, 0.75% by mass or more, or 1.0% by mass or more from the viewpoint of dispersibility, or may be 20% by mass or less, 15% by mass or less, or 8% by mass or less from the viewpoint of water absorbability, on the basis of the total amount of the monomer units constituting the polymer (a).

The polymer (a) has a styrene or styrene derivative unit (a structure unit derived from a styrene or styrene derivative) and the content of the styrene or styrene derivative unit is 40% by mass or more on the basis of the total amount of the monomer units constituting the polymer (a). The styrene derivative may be, for example, vinyl toluene, α-methylstyrene, and the like.

The content of the styrene and the styrene derivative in the polymer (a) is 40% by mass or more on the basis of the total amount of the monomer units constituting the polymer (a), may be 45% by mass or more, 47% by mass or more, or 50% by mass or more from the viewpoint of resolution, or may be 90% by mass or less, 85% by mass or less, or 80% by mass or less from the viewpoint of developability.

The polymer (a) may have a structure unit derived from (meth)acrylic acid in addition to the above-described structure unit, or may further have a structure unit derived from a monomer other than the (meth)acrylic acid. The other monomer may be one or two or more kinds.

The other monomer may be, for example, (meth)acrylic acid ester. Examples of the (meth)acrylic acid ester include alkyl (meth)acrylate ester, cycloalkyl (meth)acrylate ester, and aryl (meth)acrylate ester.

From the viewpoint of improving alkali developability and release property, the other monomer may be preferably alkyl (meth)acrylate ester. The alkyl group of the alkyl (meth)acrylate ester may be, for example, a methyl group, an ethyl group, a propyl group, a butyl group, a pentyl group, a hexyl group, a heptyl group, an octyl group, a nonyl group, a decyl group, an undecyl group, a dodecyl group, or a structural isomer thereof, and may be an alkyl group having 1 to 4 carbon atoms from the viewpoint of further improving release property.

In a case where the other monomer is alkyl (meth)acrylate ester, the content of the alkyl (meth)acrylate ester may be 1% by mass or more, 2% by mass or more, or 3% by mass or more from the viewpoint of superior release property, or may be 80% by mass or less, 60% by mass or less, or 50% by mass or less from the viewpoint of further improving resolution and adhesiveness, on the basis of the total amount of the monomers constituting the component (A).

Furthermore, examples of the other monomer include acrylamides such as diacetoneacrylamide, vinyl alcohol ethers such as acrylonitrile and vinyl-n-butyl ether, benzyl (meth)acrylate esters such as alkyl (meth)acrylate ester and benzyl methacrylate, tetrahydrofurfuryl (meth)acrylate ester, dimethylaminoethyl (meth)acrylate ester, diethylaminoethyl (meth)acrylate ester, glycidyl (meth)acrylate ester, 2,2,2-trifluoroethyl (meth)acrylate, 2,2,3,3-tetrafluoropropyl (meth)acrylate, α-bromoacrylic acid, α-chloracrylic acid, β-furyl(meth)acrylic acid, β-styryl(meth)acrylic acid, maleic acid, maleic anhydride, maleic acid monoesters such as monomethyl malate, monoethyl malate, and monoisopropyl malate, fumaric acid, cinnamic acid, α-cyanocinnamic acid, itaconic acid, crotonic acid, and propiolic acid.

The component (A) may contain a binder polymer other than the above-described polymer (a), and may be composed of only the polymer (a). From the viewpoint of obtaining more superior adhesiveness and resolution, the content of the polymer (a) in the component (A) may be 50 to 100% by mass, or may be 80 to 100% by mass, on the basis of the total amount of the component (A).

The acid value of the polymer (a) may be 100 mgKOH/g or more, 120 mgKOH/g or more, 140 mgKOH/g or more, or 150 mgKOH/g or more from the viewpoint that developing can be suitably performed, or may be 250 mgKOH/g or less, 240 mgKOH/g or less, or 230 mgKOH/g or less from the viewpoint of improving the adhesiveness (developing solution resistance) of a cured product of the photosensitive resin composition. The acid value of the polymer (a) can be adjusted by the content of the structure unit constituting the polymer (a) (for example, a structure unit derived from (meth)acrylic acid). In a case where the component (A) contains a binder polymer other than the polymer (a), the acid value of the other binder polymer may also be within the above range.

The weight average molecular weight (Mw) of the polymer (a) may be 10000 or more, 20000 or more, 25000 or more, or 30000 or more from the viewpoint of attaining superior adhesiveness (developing solution resistance) of a cured product of the photosensitive resin composition, or may be 100000 or less, 80000 or less, 60000 or less, or 40000 or less from the viewpoint that developing can be suitably performed. The degree of dispersion (Mw/Mn) of the polymer (a) may be, for example, 1.0 or more or 1.5 or more, and may be 3.0 or less or 2.5 or less from the viewpoint of further improving adhesiveness and resolution. In a case where the component (A) contains a binder polymer other than the polymer (a), the Mw of the other binder polymer may also be within the above range.

The weight average molecular weight and the degree of dispersion can be measured, for example, by gel permeation chromatography (GPC) using a calibration curve of standard polystyrene. More specifically, the weight average molecular weight and the degree of dispersion can be measured under conditions described in Examples. Note that, as for a compound having a low molecular weight, in a case where measurement of the weight average molecular weight is difficult using the above-described measurement method, it is also possible to measure the molecular weights using other methods and to calculate an average thereof.

The content of the component (A) may be 20% by mass or more, 30% by mass or more, or 40% by mass or more from the viewpoint of attaining superior film moldability, or may be 90% by mass or less, 80% by mass or less, or 65% by mass or less from the viewpoint of attaining further superior sensitivity and resolution, on the basis of the total amount of solid contents of the photosensitive resin composition.

The content of the component (A) may be 30 parts by mass or more, 35 parts by mass or more, or 40 parts by mass or more from the viewpoint of attaining superior film moldability, or may be 70 parts by mass or less, 65 parts by mass or less, or 60 parts by mass or less from the viewpoint of further improving sensitivity and resolution, with respect to 100 parts by mass of the total amount of the component (A) and the component (B).

Component (B): Photopolymerizable Compound

The photosensitive resin composition contains one or two or more kinds of the components (B). The component (B) may be a compound that is polymerized with light, and may be, for example, a compound having an ethylenic unsaturated bond. The component (B) may contain a polyfunctional monomer having two or more reactive groups reacting with radicals. From the viewpoint of further improving alkali developability, resolution, and release property after curing, the component (B) may contain a bisphenol A-type (meth)acrylate compound.

Examples of the bisphenol A-type (meth)acrylate compound include 2,2-bis(4-((meth)acryloxypolyethoxy)phenyl)propane (such as 2,2-bis(4-((meth)acryloxypentaethoxy)phenyl)propane), 2,2-bis(4-((meth)acryloxypolypropoxy)phenyl)propane, 2,2-bis(4-((meth)acryloxypolybutoxy)phenyl)propane, and 2,2-bis(4-((meth)acryloxypolyethoxypolypropoxy)phenyl)propane. The component (B) may contain 2,2-bis(4-((meth)acryloxypolyethoxy)phenyl)propane (such as 2,2-bis(4-((meth)acryloxypentaethoxy)phenyl)propane) from the viewpoint of further improving resolution and release property. As the 2,2-bis(4-((meth)acryloxypolyethoxy)phenyl)propane, a compound in which the number of oxyethylene groups is 10 or more may be used, a compound in which the number of oxyethylene groups is less than 10 may be used, and a compound in which the number of oxyethylene groups is 10 or more and a compound in which the number of oxyethylene groups is less than 10 may be used in combination.

The content of the bisphenol A-type (meth)acrylate compound may be 20% by mass or more or 40% by mass or more, or may be 100% by mass or less, 95% by mass or less, or 90% by mass or less, on the basis of the total amount of the component (B), from the viewpoint of further improving resolution of a resist.

The component (B) may contain an α,β-unsaturated ester compound obtained by reacting polyhydric alcohol with α,β-unsaturated carboxylic acid from the viewpoint of further suitably improving resolution and flexibility. Examples of the α,β-unsaturated ester compound include polyalkylene glycol di(meth)acrylate such as polyethylene glycol di(meth)acrylate, polypropylene glycol di(meth)acrylate and EO-modified polypropylene glycol, trimethylolpropane di(meth)acrylate, trimethylolpropane tri(meth)acrylate, EO-modified trimethylolpropane tri(meth)acrylate, PO-modified trimethylolpropane tri(meth)acrylate, EO, PO-modified trimethylolpropane tri(meth)acrylate, tetramethylolmethane tri(meth)acrylate, and tetramethylolmethane tetra(meth)acrylate.

The component (B) may contain a compound having three or more (meth)acryloyl groups from the viewpoint of improving sensitivity and adhesiveness. As such a compound, trimethylolpropane tri(meth)acrylate, EO-modified trimethylolpropane tri(meth)acrylate, PO-modified trimethylolpropane tri(meth)acrylate, EO, PO-modified trimethylolpropane tri(meth)acrylate, EO-modified pentaerythritol tetra(meth)acrylate, EO-modified ditrimethylolpropane tetra(meth)acrylate, and EO-modified dip entaerythritol hexa(meth)acrylate may be included.

The content of the α,β-unsaturated ester compound may be 20% by mass or more or 30% by mass or more from the viewpoint of improving flexibility, or may be 70% by mass or less or 60% by mass or less from the viewpoint of further improving resolution, on the basis of the total amount of the component (B).

The photosensitive resin composition may contain, as the component (B), a photopolymerizable compound other than the bisphenol A-based (meth)acrylate compound and the α,β-unsaturated ester compound.

Examples of the other photopolymerizable compound include nonylphenoxypolyethylene oxyacrylate, a phthalic acid-based compound, alkyl (meth)acrylate ester, and photopolymerizable compounds with at least one cationic polymerizable cyclic ether group in the molecule (such as an oxetane compound). The other photopolymerizable compound may be at least one selected from the group consisting of nonylphenoxypolyethylene oxyacrylate and a phthalic acid-based compound from the viewpoint of further suitably improving resolution, adhesiveness, resist shape, and release property after curing.

Examples of the nonylphenoxypolyethylene oxyacrylate include nonylphenoxytriethylene oxyacrylate, nonylphenoxytetraethylene oxyacrylate, nonylphenoxypentaethylene oxyacrylate, nonylphenoxyhexaethylene oxyacrylate, nonylphenoxyheptaethylene oxyacrylate, nonylphenoxyoctaethylene oxyacrylate, nonylphenoxynonaethylene oxyacrylate, nonylphenoxydecaethylene oxyacrylate, and nonylphenoxyundecaethylene oxyacrylate.

The phthalic acid-based compound may be, for example, γ-chloro-β-hydroxypropyl-β′-(meth)acryloyloxyethyl-o-phthalate (also known as: 3-chloro-2-hydroxypropyl-2-(meth)acryloyloxyethyl phthalate), β-hydroxyethyl-β′-(meth)acryloyloxyethyl-o-phthalate, β-hydroxypropyl-β′-(meth)acryloyloxyethyl-o-phthalate, and the like, and is preferably γ-chloro-β-hydroxypropyl-β′-(meth)acryloyloxyethyl-o-phthalate.

In a case where the component (B) contains other photopolymerizable compound, the content of the other photopolymerizable compound may be 1% by mass or more, 3% by mass or more, or 5% by mass or more, or may be 30% by mass or less, 25% by mass or less, or 20% by mass or less, on the basis of the total amount of the component (B), from the viewpoint of further suitably improving resolution, adhesiveness, resist shape, and release property after curing.

The component (B) may contain a compound having 2 to 40 of oxyethylene groups (EO groups) and/or oxypropylene groups (PO groups) in total in the molecule among the above-described compounds, from the viewpoint of further improving adhesiveness and resolution. The total number of EO groups and/or PO groups may be 2 to 40 or 2 to 30 from the viewpoint of further improving adhesiveness and resolution.

The content of the compound having 2 to 40 of the EO groups and/or the PO groups in total may be 2 to 15% by mass, 4 to 12% by mass, or 5 to 8% by mass, on the basis of the total amount of the component (B), from the viewpoint of further improving adhesiveness and resolution.

The content of the component (B) may be 3% by mass or more, 10% by mass or more, or 25% by mass or more from the viewpoint of further improving sensitivity and resolution, or may be 70% by mass or less, 60% by mass or less, or 50% by mass or less from the viewpoint of attaining superior film moldability, on the basis of the total amount of solid contents of the photosensitive resin composition.

Component (C): Photopolymerization Initiator

The photosensitive resin composition contains one or two or more kinds of the components (C). Examples of the component (C) include a hexaarylbiimidazole compound; aromatic ketones such as benzophenone, 2-benzyl-2-dimethylamino-1-(4-morpholinophenyl)-1-butanone, 2-(dimethylamino)-2-[(4-methylphenyl)methyl]-1-[4-(4-morpholinyl)phenyl]-1-butanone, 4-(2-hydroxyethoxy)phenyl-2-(hydroxy-2-propyl)ketone, and 2-methyl-1-[4-(methylthio)phenyl]-2-morpholino-propanone-1; quinones such as alkylanthraquinone; benzoinether compounds such as benzoinalkyl ethers; benzoin compounds such as benzoin and alkylbenzoin; benzyl derivatives such as benzyldimethylketal; bis(2,4,6-trimethylbenzoyl)-phenylphosphine oxide; bis(2,6-dimethylbenzoyl)-2,4,4-trimethyl-pentylphosphine oxide; and (2,4,6-trimethylbenzoyl)ethoxyphenylphosphine oxide.

The component (C) may contain a hexaarylbiimidazole compound from the viewpoint that penetration of a photosensitizer into a polyethylene film can be further suppressed. The aryl group in the hexaarylbiimidazole compound may be a phenyl group and the like. A hydrogen atom bonded to the aryl group in the hexaarylbiimidazole compound may be substituted with a halogen atom (a chlorine atom or the like).

The hexaarylbiimidazole compound may be a 2,4,5-triarylimidazole dimer. Examples of the 2,4,5-triarylimidazole dimer include a 2-(o-chlorophenyl)-4,5-diphenylimidazole dimer, a 2-(o-chlorophenyl)-4,5-bis-(m-methoxyphenyl)imidazole dimer, and a 2-(p-methoxyphenyl)-4,5-diphenylimidazole dimer. The hexaarylbiimidazole compound is preferably a 2-(o-chlorophenyl)-4,5-diphenylimidazole dimer and more preferably 2,2-bis(o-chlorophenyl)-4,5-4′,5′-tetraphenyl-1,2′biimidazole, from the viewpoint that penetration of a photosensitizer into a polyethylene film can be further suppressed.

The content of the hexaarylbiimidazole compound may be 90% by mass or more, 95% by mass or more, or 99% by mass or more on the basis of the total amount of the component (C), from the viewpoint that penetration of a photosensitizer into a polyethylene film can be further suppressed. The component (C) may be composed of only the hexaarylbiimidazole compound.

The content of the component (C) may be 0.1% by mass or more, 0.5% by mass or more, or 1% by mass or more, or may be 20% by mass or less, 10% by mass or less, or 5% by mass or less, on the basis of the total amount of solid contents of the photosensitive resin composition, from the viewpoint of further improving sensitivity and adhesiveness.

Component (D): Anthracene-Based Sensitizer

The photosensitive resin composition contains one or two or more kinds of the components (D). The component (D) is used as a photosensitizer. Examples of the component (D) include 9,10-dibutoxyanthracene, 9,10-diphenylanthracene, and 9,10-diethoxyanthracene. Among these, from the viewpoint of further improving adhesiveness and resolution, 9,10-dibutoxyanthracene is preferred.

The content of the component (D) is, for example, 0.2 parts by mass or more, preferably 0.3 parts by mass or more, more preferably 0.4 parts by mass or more, and further preferably 0.5 parts by mass or more from the viewpoint of further improving sensitivity, adhesiveness, and resolution, or is, for example, 1.5 parts by mass or less, preferably 1.0 part by mass or less, more preferably 0.8 parts by mass or less, further preferably less than 0.8 parts by mass, and particularly preferably 0.7 parts by mass or less from the viewpoint of attaining a more favorable resist pattern shape, with respect to 100 parts by mass of the total amount of the component (A) and the component (B). Furthermore, when the content of the component (D) is less than 0.8 parts by mass, it is possible to attain favorable storage stability of the photosensitive element when the photosensitive element is formed. Specifically, for example, it is possible to suppress the component (D) from being precipitated on the surface of the photosensitive resin layer (between the photosensitive resin layer and the protective layer in a case where the photosensitive element includes the protective layer) when the photosensitive element is stored in a refrigerator. Note that, the precipitation of the component (D) is likely to occur in a case where 9,10-dibutoxyanthracene is used as the component (D) and the protective layer is a polyethylene film, but even in the case of adopting such a combination, when the content of the component (D) is set to be less than 0.8 parts by mass, the precipitation of the component (D) during storage in a refrigerator can be suppressed.

The photosensitive resin composition may further contain a known photosensitizer as the other photosensitizer, in addition to the component (D). The content of the other sensitizer may be, for example, 0.2 to 1.5 parts by mass or 0.4 to 1.0 part by mass with respect to 100 parts by mass of the total amount of the component (A) and the component (B).

Component (E): Polymerization Inhibitor

The photosensitive resin composition may further contain a component (E): a polymerization inhibitor from the viewpoint of suppressing the polymerization in an unexposed area during resist pattern formation and further improving resolution. The polymerization inhibitor may be, for example, t-butylcatechol, 4-hydroxy-2,2,6,6-tetramethylpiperidine-N-oxyl, and the like.

The content of the component (E) may be 0.001 parts by mass or more, 0.002 parts by mass or more, or 0.003 parts by mass or more from the viewpoint of sensitivity and resolution, or may be 0.1 parts by mass or less, 0.05 parts by mass or less, or 0.01 parts by mass or less from the viewpoint of sensitivity and adhesiveness, with respect to 100 parts by mass of the total amount of the component (A) and the component (B).

The photosensitive resin composition may further contain one or two or more kinds of components other than the above-described components. Examples of the other components include hydrogen donors (such as bis[4-(dimethylamino)phenyl]methane, bis[4-(diethylamino)phenyl]methane, leuco crystal violet, and N-phenylglycine), dyes (such as malachite green), tribromophenylsulfone, photochromic agents, thermal development inhibitors, plasticizers (such as p-toluenesulfonamide), pigments, fillers, antifoaming agents, flame retardants, stabilizers, tackifiers, leveling agents, release promoters, antioxidants, aromatics, imaging agents, and thermal crosslinking agents. The content of the other components may be 0.005 parts by mass or more or 0.01 parts by mass or more, or may be 20 parts by mass or less, with respect to 100 parts by mass of the total amount of the component (A) and the component (B).

The photosensitive resin composition may further contain one or two or more kinds of organic solvents from the viewpoint of adjusting the viscosity. Examples of the organic solvent include methanol, ethanol, acetone, methyl ethyl ketone, methyl cellosolve, ethyl cellosolve, toluene, N,N-dimethylformamide, and propylene glycol monomethyl ether. The content of the organic solvent may be 40% by mass or more or may be 70% by mass or less on the basis of the total amount of the photosensitive resin composition.

The photosensitive resin composition can be suitably used in formation of a resist pattern and can be particularly suitably used in a method for producing a wiring board described below.

<Photosensitive Element 22

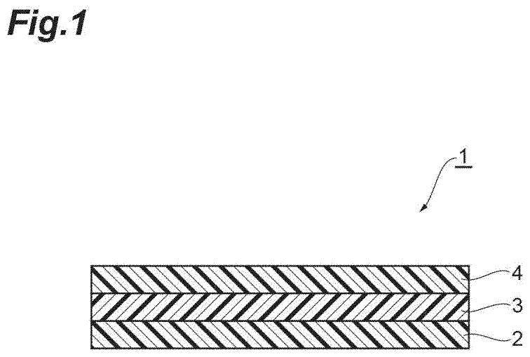

FIG. 1 is a schematic cross-sectional view of a photosensitive element according to an embodiment. As illustrated in FIG. 1, a photosensitive element 1 includes a support 2, a photosensitive resin layer 3 provided on the support 2, and a protective layer 4 provided on a side of the photosensitive resin layer 3, the side being opposite from the support 2.

Each of the support 2 and the protective layer 4 may be a polymer film having heat resistance and solvent resistance, and may be, for example, a polyester film such as a polyethylene terephthalate film, a polyolefin film such as a polyethylene film or a polypropylene film, and the like. Each of the support 2 and the protective layer 4 may be a film of a hydrocarbon-based polymer other than polyolefin. The hydrocarbon-based polymer film containing polyolefin may have a low density, or may have, for example, a density of 1.014 g/cm³ or less. Each of the support 2 and the protective layer 4 may be a stretched film obtained by stretching the low-density hydrocarbon-based polymer film. The type of the polymer film constituting the protective layer 4 may be the same as or different from the type of the polymer film constituting the support 2.

These polymer films each are commercially available, for example, as polyethylene terephthalate films such as PS series (for example, PS-25) manufactured by TEIJIN LIMITED, polyethylene films such as NF-15 manufactured by TAMAPOLY CO., LTD., or polypropylene films manufactured by Oji Paper Co., Ltd. (for example, ALPHAN MA-410 and E-200C), polypropylene films manufactured by Shin-Etsu Film Co., Ltd., and the like.

The thickness of the support 2 may be 1 μm or more or 5 μm or more from the viewpoint that breakage of the support 2 can be suppressed when the support 2 is released from the photosensitive resin layer 3, or may be 100 μm or less, 50 μm or less, or 30 μm or less from the viewpoint that exposure can be suitably performed even in the case of exposure through the support 2.

The thickness of the protective layer 4 may be 1 μm or more, 5 μm or more, or 15 μm or more from the viewpoint that breakage of the protective layer 4 can be suppressed when the photosensitive resin layer 3 and the support 2 are laminated on the substrate while releasing the protective layer 4, or may be 100 μm or less, 50 μm or less, or 30 μm or less from the viewpoint of improving productivity.

The photosensitive resin layer 3 is made of the above-described photosensitive resin composition. The post-drying thickness of the photosensitive resin layer 3 (after the organic solvent is volatilized in a case where the photosensitive resin composition contains the organic solvent) may be 1 μm or more or 5 μm or more from the viewpoint of facilitating coating and improving productivity, or may be 100 μm or less, 50 μm or less, or 40 μm or less from the viewpoint of further improving adhesiveness and resolution.

The photosensitive element 1 can be obtained, for example, as follows. First, the photosensitive resin layer 3 is formed on the support 2. The photosensitive resin layer 3 can be formed, for example, by applying a photosensitive resin composition containing an organic solvent to form a coating layer and drying this coating layer. Next, the protective layer 4 is formed on a surface of the photosensitive resin layer 3, the surface being on the opposite side from the support 2.

The coating layer is formed, for example, by known methods such as roll coating, comma coating, gravure coating, air knife coating, die coating, and bar coating. The drying of the coating layer is performed so that the amount of the organic solvent remaining in the photosensitive resin layer 3 is, for example, 2% by mass or less, and specifically, is performed, for example, at 70 to 150° C. for 5 to 30 minutes.

In another embodiment, the photosensitive element may not include a protective layer, and may further include other layers such as a cushion layer, an adhesive layer, a light absorbing layer, and a gas barrier layer.

The photosensitive element 1 may be, for example, in a sheet form, or may be in the form of a photosensitive element roll being wound around a core into a roll. In the photosensitive element roll, the photosensitive element 1 is preferably wound such that the support 2 comes on the outer side. The core is formed, for example, with polyethylene, polypropylene, polystyrene, polyvinyl chloride, an acrylonitrile-butadiene-styrene copolymer, or the like. At the end faces of the photosensitive element roll, end-face separators may be provided from the viewpoint of protecting the end faces, and moisture-proof end-face separators may be provided from the viewpoint of resistance to edge fusion. The photosensitive element 1 may be wrapped, for example, with a black sheet having low moisture permeability.

The photosensitive element 1 can be suitably used in formation of a resist pattern and can be particularly suitably used in a method for producing a wiring board described below.

<Method for Producing Wiring Board>

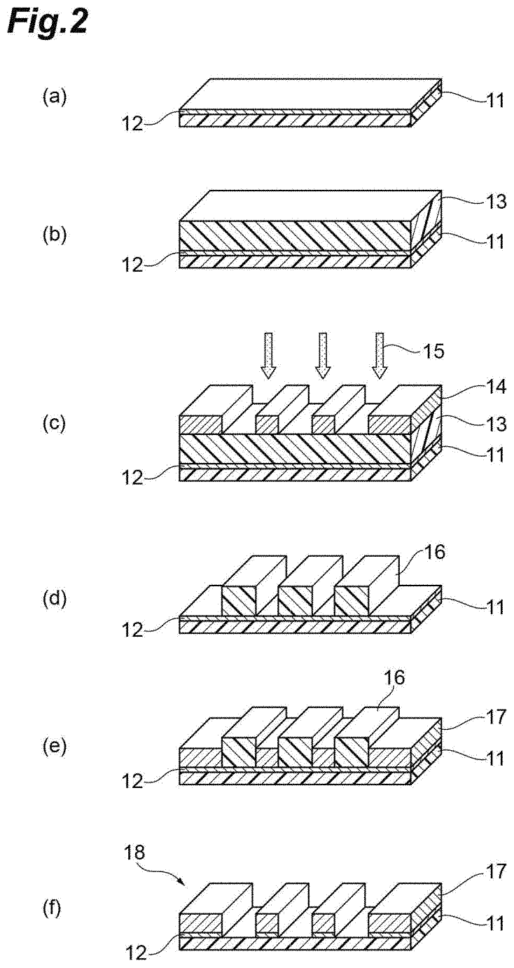

FIG. 2 is a schematic view illustrating a method for producing a wiring board (also called a printed wiring board) according to an embodiment. In the production method, first, as illustrated in FIG. 2(a), a substrate (for example, a substrate for circuit formation) including an insulation layer 11 and a conductor layer 12 formed on the insulation layer 11 is prepared. The conductor layer 12 may be, for example, a metal copper layer.

Next, as illustrated in FIG. 2(b), a photosensitive resin layer 13 is provided on the substrate (the conductor layer 12). In this step, the photosensitive resin layer 13 made of the above-described photosensitive resin composition is formed on the substrate (the conductor layer 12) by using the above-described photosensitive resin composition or the photosensitive element 1. For example, the photosensitive resin layer 13 is formed by applying the photosensitive resin composition onto the substrate and drying the photosensitive resin composition. Alternatively, the photosensitive resin layer 13 is formed by removing the protective layer 4 from the photosensitive element 1 and then pressure-bonding the photosensitive resin layer 3 of the photosensitive element 1 to the substrate while heating. During pressure-bonding, at least one of the photosensitive resin layer 3 and the substrate may be heated, for example, at 70 to 130° C. The pressure during pressure-bonding may be, for example, 0.1 to 1.0 MPa.

Next, as illustrated in FIG. 2(c), a mask 14 is disposed on the photosensitive resin layer 13 and is irradiated with an active light ray 15 and an area other than the area on which the mask 14 is disposed is exposed to photo-cure the photosensitive resin layer 13. The light source for the active light ray 15 may be, for example, ultraviolet light sources or visible light sources such as a carbon arc lamp, a mercury vapor arc lamp, a high-pressure mercury lamp, a xenon lamp, a gas laser (such as an argon laser), a solid-state laser (such as a YAG laser), and a semiconductor laser.

In another embodiment, an area may be irradiated with the active light ray 15 through a desired pattern by a direct imaging exposure method, such as an LDI exposure method or a DLP exposure method, without using the mask 14 to expose a part of the photosensitive resin layer 13.

Next, as illustrated in FIG. 2(d), an area (uncured area) other than the photo-cured area formed by exposure is removed from the substrate by development to form a resist pattern 16 including the photo-cured area (a cured product of the photosensitive resin layer). The development method may be, for example, wet development or dry development, and the wet development is preferred.

The wet development is performed using a developing solution suitable for the photosensitive resin composition, for example, by methods such as a dip method, a paddle method, a spray method, brushing, slapping, scrubbing, and dipping while shaking. The developing solution is appropriately selected in accordance with the configuration of the photosensitive resin composition, and may be an alkaline developing solution or an organic solvent developing solution.

The alkaline developing solution may be aqueous solutions containing bases such as alkali hydroxides such as hydroxides of lithium, sodium, or potassium; alkali carbonates such as carbonates or bicarbonates of lithium, sodium, potassium, or ammonium; alkali metal phosphates such as potassium phosphate and sodium phosphate; alkali metal pyrophosphate such as sodium pyrophosphate and potassium pyrophosphate; borax; sodium metasilicate; tetramethylammonium hydroxide; ethanolamine; ethylenediamine; diethylene triamine; 2-amino-2-hydroxymethyl-1,3-propanediol; 1,3-diamino-2-propanol; and morpholine.

The alkaline developing solution may be, for example, a 0.1 to 5% by mass sodium carbonate aqueous solution, a 0.1 to 5% by mass potassium carbonate aqueous solution, a 0.1 to 5% by mass sodium hydroxide aqueous solution, a 0.1 to 5% by mass sodium tetraborate aqueous solution, and the like. The pH of the alkaline developing solution may be, for example, 9 to 11.

The alkaline developing solution may further contain a surfactant, an antifoaming agent, an organic solvent, and the like. Examples of the organic solvent include acetone, ethyl acetate, alkoxyethanol having an alkoxy group having 1 to 4 carbon atoms, ethyl alcohol, isopropyl alcohol, butyl alcohol, diethylene glycol monomethyl ether, diethylene glycol monoethyl ether, and diethylene glycol monobutyl ether. The content of the organic solvent may be 2 to 90% by mass on the basis of the total amount of the alkaline developing solution.

The organic solvent developing solution may contain organic solvents such as 1,1,1-trichloroethane, N-methylpyrrolidone, N,N-dimethylformamide, cyclohexanone, methyl isobutyl ketone, and γ-butyrolactone. The organic solvent developing solution may further contain 1 to 20% by mass of water.

In this step, after removing the unexposed area, the resist pattern 16 may be further cured by further performing heating at 60 to 250° C. or exposure at 0.2 to 10 J/cm², as necessary.

Next, as illustrated in FIG. 2(e), a wiring layer 17 is formed on a part of the conductor layer 12 in which the resist pattern 16 is not formed, for example, by a plating treatment. The wiring layer 17 may be formed using the same material as that of the conductor layer 12, and may be formed using a material different from that of the conductor layer 12. The wiring layer 17 may be, for example, a metal copper layer. The plating treatment may be one or both of an electrolytic plating treatment and a non-electrolytic plating treatment.

Next, as illustrated in FIG. 2(f), the resist pattern 16 is removed, and at the same time, the conductor layer 12 provided at the position corresponding to the resist pattern 16 is removed. Thereby, a wiring board 18 in which the wiring layer 17 is formed on the substrate is obtained.

The resist pattern 16 can be removed, for example, using a strong alkaline aqueous solution by performing development such as a dipping method and a spraying method. The strong alkaline aqueous solution may be, for example, a 1 to 10% by mass sodium hydroxide aqueous solution, a 1 to 10% by mass potassium hydroxide aqueous solution, and the like.

The conductor layer 12 can be removed by an etching treatment. An etching solution is appropriately selected in accordance with the type of the conductor layer 12, and may be, for example, a cupric chloride solution, a ferric chloride solution, an alkali etching solution, a hydrogen peroxide etching solution, and the like.

### EXAMPLES

Hereinafter, the present disclosure will be further specifically described by means of Examples; however, the present disclosure is not limited to these Examples.

<Synthesis of Component (A)>

Monomers shown in Table 1 were mixed with 0.9 parts by mass of azobisisobutyronitrile at a blending amount (unit: parts by mass) shown in Table 1 to prepare a solution (a). 0.5 parts by mass of azobisisobutyronitrile was dissolved in 50 parts by mass of a mixed liquid (x) containing 30 parts by mass of methyl cellosolve and 20 parts by mass of toluene, thereby preparing a solution (b). In a flask equipped with a stirrer, a reflux condenser, a thermometer, a dropping funnel, and a nitrogen gas inlet tube, 500 g of the mixed liquid (x) was charged, and the resultant was stirred while blowing nitrogen gas into the flask and heated to 80° C. The solution (a) was added dropwise to the mixed liquid in the flask over 4 hours at a constant dropwise addition rate, and then the resultant was stirred at 80° C. for 2 hours. Next, the solution (b) was added dropwise to the solution in the flask over 10 minutes at a constant dropwise addition rate, and then the solution in the flask was stirred at 80° C. for 3 hours. Further, the solution in the flask was heated to 90° C. over 30 minutes and kept at 90° C. for 2 hours, and stopped stirring, and cooled to room temperature (25° C.), thereby obtaining solutions of binder polymers A1 to A9. The non-volatile content (solid content) of each of solutions of the binder polymers A1 to A9 was 49% by mass. The weight average molecular weight (Mw) of each of the binder polymers A1 to A9 is shown in Table 1.

Note that, the weight average molecular weight was measured by gel permeation chromatography (GPC) and was derived by conversion using a calibration curve of standard polystyrene.

Conditions for GPC are as described below.

### (GPC Conditions)

Pump: Hitachi L-6000 type (manufactured by Hitachi, Ltd., trade name)
Column: Three columns below in total

Gelpack GL-R420

Gelpack GL-R430

Gelpack GL-R440 (above all, manufactured by Hitachi Chemical Co., Ltd., trade name)

### Eluent: Tetrahydrofuran

Measurement temperature: 40° C.
Flow rate: 2.05 mL/min
Detector: Hitachi L-3300 type RI (manufactured by Hitachi, Ltd., trade name)

TABLE 1

| | Binder polymer | | | | | | | | |
|---|---|---|---|---|---|---|---|---|---|
| | A1 | A2 | A3 | A4 | A5 | A6 | A7 | A8 | A9 |
| Methacrylic acid | 27 | 27 | 24 | 27 | 27 | 27 | 27 | 30 | 30 |
| Methyl methacrylate | — | — | — | — | — | 5 | 7.3 | — | — |
| Styrene | 50 | 45 | 45 | 45 | 47 | 45 | 7.3 | 35 | 20 |
| Benzyl methacrylate | 20 | 20 | 20 | 23 | 23 | 23 | 58.4 | 30 | 50 |
| 2-Hydroxyethyl methacrylate | 3 | 3 | 3 | 5 | 3 | — | — | 5 | — |
| 2-Ethylhexyl acrylate | — | 5 | 8 | — | — | — | — | — | — |
| Weight average molecular weight | 35000 | 35000 | 35000 | 35000 | 35000 | 50000 | 50000 | 35000 | 35000 |

### Examples 1 to 16 and Comparative Examples 1 to 10

<Preparation of Photosensitive Resin Composition>

Respective components shown in Table 2 to Table 4 were mixed at blending amounts (parts by mass) shown in Table 2 to Table 4 to prepare each of photosensitive resin compositions. Note that, the blending amounts (parts by mass) of the component (A) shown in Table 2 to Table 4 are the mass of non-volatile content (solid content amount). The details of respective components shown in Table 2 to Table 4 are as follows.

Component (B)

FA-321M(70): Propylene glycol monomethyl ether 70% solution of 2,2-bis(4-(methacryloxyethoxy)phenyl)propane (an adduct of an average of 10 mol of ethylene oxide) (manufactured by Hitachi Chemical Co., Ltd.)
FA-024M: (PO)(EO)(PO)-modified dimethacrylate (manufactured by Hitachi Chemical Co., Ltd., an adduct of an average of 6 mol of ethylene oxide and an average of 12 mol of propylene oxide (total value))
BP-2EM: 2,2-Bis(4-(methacryloxypolyethoxy)phenyl)propane (manufactured by Kyoeisha Chemical Co., Ltd., EO group: 5.2 (total value))
Trifunctional monomer 1: EO-modified trimethylolpropane trimethacrylate (EO group: 21 (total value))
Tetrafunctional monomer 1: EO-modified pentaerythritol tetramethacrylate (EO group: 4 (total value))
Tetrafunctional monomer 2: EO-modified pentaerythritol tetramethacrylate (EO group: 12 (total value))
Tetrafunctional monomer 3: EO-modified ditrimethylolpropane tetramethacrylate (EO group: 4 (total value))
Tetrafunctional monomer 4: EO-modified ditrimethylolpropane tetramethacrylate (EO group: 12 (total value))
Hexafunctional monomer 1: EO-modified dipentaerythritol hexamethacrylate (EO group: 6 (total value))
Hexafunctional monomer 2: EO-modified dipentaerythritol hexamethacrylate (EO group: 18 (total value))
Hexafunctional monomer 3: EO-modified dipentaerythritol hexaacrylate (EO group: 12 (total value))

Component (C)

BCIM: 2,2′-Bis(o-chlorophenyl)-4,4′,5,5′-tetraphenyl-1,2′-biimidazole (manufactured by Hampford Research Inc.)

Component (D)

DBA: 9,10-Dibutoxyanthracene (manufactured by Kawasaki Kasei Chemicals Ltd.)
DPA: 9,10-Diphenylanthracene (manufactured by Kawasaki Kasei Chemicals Ltd.)

Component (D)′

PZ-501D: 1-Phenyl-3-(4-methoxystyryl)-5-(4-methoxyphenyl)pyrazoline (manufactured by NIPPON CHEMICAL INDUSTRIAL CO., LTD.) Component (E)
TBC: 4-t-Butylcatechol (manufactured by DIC Corporation, trade name “DIC-TBC”)

(Other Components)

LCV: Leuco crystal violet (manufactured by Yamada Chemical Co., Ltd.)
MKG: Malachite green (manufactured by OSAKA ORGANIC CHEMICAL INDUSTRY LTD.)
SF-808H: Mixture of carboxybenzotriazole, 5-amino-1H-tetrazole, and methoxypropanol (manufactured by SANWA KASEI CORP.)

### (Solvent)

### TLS: Toluene

### MAL: Methanol

### ACS: Acetone

<Production of Photosensitive Element>

A polyethylene terephthalate film (manufactured by TEIJIN LIMITED, trade name “HTF-01”) having a thickness of 16 μm was prepared as the support, the photosensitive resin composition was applied onto the support to have a uniform thickness and subsequently dried at 70° C. and 110° C. with a hot air current drier, thereby forming a photosensitive resin layer having a post-drying thickness of 25 μm. A polyethylene film (manufactured by TAMAPOLY CO., LTD., trade name “NF-15”) as the protective layer was attached onto this photosensitive resin layer, thereby obtaining a photosensitive element including the support, the photosensitive resin layer, and the protective layer laminated in this order.

<Production of Laminate>

A copper-clad laminate plate (substrate, manufactured by Hitachi Chemical Co., Ltd., trade name “MCL-E-679”) as a glass epoxy material including copper foils (thickness: 35 μm) laminated on both sides thereof was subjected to a surface treatment using a surface roughening treatment solution “MECetchBOND CZ-8100” (manufactured by MEC Co., Ltd., trade name). Next, the copper-clad laminate plate was rinsed, pickled, rinsed, and then dried with an air stream. The surface-treated copper-clad laminate plate was heated to 80° C., and the above-described photosensitive elements were respectively laminated such that the photosensitive resin layer was in contact with the copper surface while releasing the protective layer. Thereby, each laminate including the copper-clad laminate plate, the photosensitive resin layer, and the support laminated in this order was obtained. The obtained laminate was used as a test specimen in the following test. Note that, lamination was performed using a heat roll set at 110° C. at a pressure-bonding pressure of 0.4 MPa and at a roll speed of 1.5 m/min.

<Evaluation>

(Measurement of Minimum Developing Time)

The laminate was cut into a square 5 cm on each side to obtain a test specimen for minimum developing time measurement. After releasing the support from the test specimen, an unexposed photosensitive resin layer was spray-developed at a pressure of 0.15 MPa using a 1% by mass sodium carbonate aqueous solution set at 30° C., and the minimum time that allowed the removal of an unexposed area of 1 mm or more to be visually confirmed was defined as a minimum developing time. The nozzle used was of a full-cone type. The distance between the test specimen and the nozzle tip was 6 cm and the test specimen was disposed in such a manner that the center of the test specimen would coincide with the center of the nozzle. A shorter minimum developing time (unit: second) indicates satisfactory developability. The results are shown in Table 2 to Table 4.

(Evaluation of Sensitivity)

A Hitachi 41-step tablet was placed on the support of the test specimen, and the photosensitive resin layer was exposed through the support using a projection exposure machine (manufactured by Ushio Inc., product name UX-2240SM-XJ01) having a high-pressure mercury lamp with a wavelength of 365 nm with an exposure dose (irradiation energy dose) for 15 steps remaining after development of the Hitachi 41-step tablet. The optical sensitivity was evaluated using the exposure dose (unit: mJ/cm²) at this time. A smaller exposure dose indicates high optical sensitivity.

(Evaluation of Adhesiveness)

A drawing pattern with a line width (L)/space width (S) (hereinafter, referred to as “L/S”) of x/3x (x=1 to 20 (changing with an interval of 1 μm)) (unit: μm) was used for exposure (drawing) of the photosensitive resin layer of the laminate at an energy dose for 17 steps remaining on a 41-step tablet using a direct exposure machine having a blue-violet laser diode with a wavelength of 405 nm as the light source (manufactured by Via Mechanics, Ltd., product name DE-1UH).

Following the exposure, the support was released from the laminate to expose the photosensitive resin layer, and unexposed areas were removed by spraying a 1% by mass sodium carbonate aqueous solution at 30° C. for 60 seconds. After the development, the adhesiveness was evaluated by the minimum value among the line width values for resist patterns formed with cleanly removed space areas (unexposed areas), and without meandering or defecting of the line areas (exposed areas). A smaller numerical value indicates more satisfactory adhesiveness. The results are shown in Table 2 to Table 4. A case where the adhesiveness is 7 μm or less is regarded as “Pass”.

(Evaluation of Resolution)

A drawing pattern with a line width (L)/space width (S) (hereinafter, referred to as “L/S”) of x/x (x=1 to 20 (changing with an interval of 1 μm)) (unit: μm) was used for exposure (drawing) of the photosensitive resin layer of the laminate at an energy dose for 17 steps remaining on a 41-step tablet using a direct exposure machine having a blue-violet laser diode with a wavelength of 405 nm as the light source (manufactured by Via Mechanics, Ltd., product name DE-1UH).

Following the exposure, the support was released from the laminate to expose the photosensitive resin layer, and unexposed areas were removed by spraying a 1% by mass sodium carbonate aqueous solution at 30° C. for 60 seconds. After the development, the resolution was evaluated by the minimum value among the space width values for resist patterns formed with cleanly removed space areas (unexposed areas), and without meandering or defecting of the line areas (exposed areas). A smaller numerical value indicates more satisfactory resolution. The results are shown in Table 2 to Table 4. A case where the resolution is 12 μm or less is regarded as “Pass”.

(Evaluation of Storage Stability)

The above-described photosensitive element was stored at a temperature of 15° C. or lower for 30 days. After storage, the photosensitive resin layer surface (between the protective layer and the photosensitive resin layer) was observed by visual inspection from the side of the polyethylene film serving as the protective layer, and the existence of precipitated products was checked. A case where precipitated products were not confirmed was evaluated as “A”, and a case where precipitated products were confirmed was evaluated as “B”. The results are shown in Table 2 to Table 4. A case where precipitated products were not confirmed can be said that the storage stability is superior.

TABLE 2

| | | Exam- | Exam- | Exam- | Exam- | Exam- | Exam- | Exam- | Exam- | Exam- | Exam- |
|---|---|---|---|---|---|---|---|---|---|---|---|
| | | ple 1 | ple 2 | ple 3 | ple 4 | ple 5 | ple 6 | ple 7 | ple 8 | ple 9 | ple 10 |
| Component (A) | A1 | 56 | — | — | — | — | 54 | 56 | 56 | 56 | 56 |
| | A2 | — | 56 | — | — | — | — | — | — | — | — |
| | A3 | — | — | 56 | — | — | — | — | — | — | — |
| | A4 | — | — | — | 54 | — | — | — | — | — | — |
| | A5 | — | — | — | — | 54 | — | — | — | — | — |
| Component (B) | FA-321M(70) | 35 | 35 | 35 | 26 | 26 | 26 | 32 | 32 | 34 | 34 |
| | FA-024M | 4 | 4 | 4 | 7 | 7 | 7 | 7 | 7 | 5 | 5 |
| | BP-2EM | 5 | 5 | 5 | 5 | 5 | 5 | — | — | — | — |
| | Trifunctional | — | — | — | 3 | 3 | 3 | — | — | — | — |
| | monomer 1 | | | | | | | | | | |
| | Tetrafunctional | — | — | — | — | — | — | 5 | — | — | — |
| | monomer 1 | | | | | | | | | | |
| | Tetrafunctional | — | — | — | — | — | — | — | 5 | — | — |
| | monomer 2 | | | | | | | | | | |
| | Tetrafunctional | — | — | — | — | — | — | — | — | 5 | — |
| | monomer 3 | | | | | | | | | | |
| | Tetrafunctional | — | — | — | — | — | — | — | — | — | 5 |
| | monomer 4 | | | | | | | | | | |
| | Hexafunctional | — | — | — | 5 | 5 | 5 | — | — | — | — |
| | monomer 3 | | | | | | | | | | |
| Component (C) | BCIM | 5.0 | 5.0 | 5.0 | 4.5 | 4.5 | 4.5 | 5.0 | 5.0 | 5.0 | 5.0 |
| Component (D) | DBA | 0.65 | 0.65 | 0.65 | 0.65 | 0.65 | 0.65 | 0.65 | 0.65 | 0.65 | 0.65 |
| Component (E) | TBC | 0.01 | 0.01 | 0.01 | 0.005 | 0.005 | 0.005 | 0.005 | 0.005 | 0.005 | 0.005 |
| Other | LCV | 0.5 | 0.5 | 0.5 | 0.5 | 0.5 | 0.5 | 0.5 | 0.5 | 0.5 | 0.5 |
| components | MKG | 0.01 | 0.01 | 0.01 | 0.01 | 0.01 | 0.01 | 0.01 | 0.01 | 0.01 | 0.01 |
| | SF-808H | 0.5 | 0.5 | 0.5 | 0.5 | 0.5 | 0.5 | 0.5 | 0.5 | 0.5 | 0.5 |
| Solvent | TLS | 14 | 14 | 14 | 14 | 14 | 14 | 14 | 14 | 14 | 14 |
| | MAL | 5 | 5 | 5 | 5 | 5 | 5 | 5 | 5 | 5 | 5 |
| | ACS | 5 | 5 | 5 | 5 | 5 | 5 | 5 | 5 | 5 | 5 |

| | | | | | | | | | | |
|---|---|---|---|---|---|---|---|---|---|---|
| Minimum developing time (sec) | 18 | 16 | 17 | 13 | 12 | 13 | 15 | 14 | 17 | 15 |
| Sensitivity (mJ/cm²) | 61 | 57 | 57 | 46 | 46 | 46 | 45 | 43 | 62 | 60 |
| Adhesiveness (μm) | 6 | 6 | 7 | 7 | 7 | 7 | 7 | 7 | 7 | 7 |
| Resolution (μm) | 9 | 9 | 9 | 10 | 12 | 10 | 10 | 10 | 10 | 12 |
| Storage stability | A | A | A | A | A | A | A | A | A | A |

TABLE 3

| | | | | Compar- | Compar- | Compar- | Compar- | Compar- | Compar- | Compar- | Compar- |
|---|---|---|---|---|---|---|---|---|---|---|---|
| | | | | ative | ative | ative | ative | ative | ative | ative | ative |
| | | Exam- | Exam- | Exam- | Exam- | Exam- | Exam- | Exam- | Exam- | Exam- | Exam- |
| | | ple 11 | ple 12 | ple 1 | ple 2 | ple 3 | ple 4 | ple 5 | ple 6 | ple 7 | ple 8 |
| Component (A) | A1 | 56 | 56 | — | — | — | — | — | 56 | — | — |
| | A4 | — | — | — | — | — | — | — | — | 56 | 56 |
| | A6 | — | — | 55 | 55 | 56 | — | — | — | — | — |
| | A7 | — | — | — | — | — | 54 | — | — | — | — |
| | A8 | — | — | — | — | — | — | 56 | — | — | — |
| Component (B) | FA-321M(70) | 32 | 32 | 45 | 33 | 35 | 26 | 35 | 35 | 35 | 26 |
| | FA-024M | 7 | 7 | — | 5 | 4 | 7 | 4 | 4 | 4 | 6 |
| | BP-2EM | — | — | — | 7 | 5 | 5 | 5 | 5 | 5 | 4 |
| | Trifunctional | — | — | — | — | — | 3 | — | — | — | 3 |
| | monomer 1 | | | | | | | | | | |
| | Hexafunctional | 5 | — | — | — | — | — | — | — | — | — |
| | monomer 1 | | | | | | | | | | |
| | Hexafunctional | — | 5 | — | — | — | — | — | — | — | — |
| | monomer 2 | | | | | | | | | | |
| | Hexafunctional | — | — | — | — | — | 5 | — | — | — | 5 |
| | monomer 3 | | | | | | | | | | |
| Component (C) | BCIM | 5.0 | 5.0 | 4.5 | 4.5 | 5.0 | 4.5 | 5.0 | 5.0 | 5.0 | 5.0 |
| Component (D) | DBA | 0.65 | 0.65 | 0.65 | 0.65 | 0.65 | 0.65 | 0.65 | — | — | — |
| Component (D)′ | PZ-501D | — | — | — | — | — | — | — | 0.2 | 0.2 | 0.2 |
| Component (E) | TBC | 0.005 | 0.005 | 0.002 | 0.005 | 0.01 | 0.005 | 0.01 | 0.01 | 0.01 | 0.01 |
| Other | LCV | 0.5 | 0.5 | 0.5 | 0.5 | 0.5 | 0.5 | 0.5 | 0.5 | 0.5 | 0.5 |
| components | MKG | 0.01 | 0.01 | 0.03 | 0.03 | 0.01 | 0.01 | 0.01 | 0.01 | 0.01 | 0.01 |
| | SF-808H | 0.5 | 0.5 | 0.5 | 0.5 | 0.5 | 0.5 | 0.5 | 0.5 | 0.5 | 0.5 |
| Solvent | TLS | 14 | 14 | 14 | 14 | 14 | 14 | 14 | 14 | 14 | 14 |
| | MAL | 5 | 5 | 5 | 5 | 5 | 5 | 5 | 5 | 5 | 5 |
| | ACS | 5 | 5 | 5 | 5 | 5 | 5 | 5 | 5 | 5 | 5 |

| | | | | | | | | | | |
|---|---|---|---|---|---|---|---|---|---|---|
| Minimum developing time (sec) | 15 | 15 | 16 | 22 | 23 | 12 | 15 | 17 | 15 | 11 |
| Sensitivity (mJ/cm²) | 48 | 44 | 41 | 52 | 57 | 41 | 52 | 55 | 54 | 59 |
| Adhesiveness (μm) | 7 | 7 | 10 | 9 | 8 | 9 | 9 | 8 | 8 | 8 |
| Resolution (μm) | 10 | 10 | 14 | 12 | 10 | 14 | 16 | 10 | 12 | 12 |
| Storage stability | A | A | A | A | A | A | A | A | A | A |

TABLE 4

| | | Comparative | Comparative | Comparative | Comparative | Comparative |
|---|---|---|---|---|---|---|
| | | Example 13 | Example 14 | Example 15 | Example 16 | Example 9 |
| Component (A) | A1 | 56 | 56 | 56 | 56 | — |
| | A9 | — | — | — | — | 56 |
| Component (B) | FA-321M(70) | 35 | 35 | 35 | 40 | 35 |
| | FA-024M | 4 | 4 | 4 | 4 | 4 |
| | BP-2EM | 5 | 5 | 5 | — | 5 |
| Component (C) | BCIM | 5.0 | 5.0 | 5.0 | 5.0 | 5.0 |
| Component (D) | DBA | — | — | 0.80 | 0.65 | 0.65 |
| | DPA | 0.65 | 0.80 | — | — | — |
| Component (E) | TBC | 0.01 | 0.01 | 0.01 | 0.01 | 0.01 |
| Other | LCV | 0.5 | 0.5 | 0.5 | 0.5 | 0.5 |
| components | MKG | 0.01 | 0.01 | 0.01 | 0.01 | 0.01 |
| | SF-808H | 0.5 | 0.5 | 0.5 | 0.5 | 0.5 |
| Solvent | TLS | 14 | 14 | 14 | 14 | 14 |
| | MAL | 5 | 5 | 5 | 5 | 5 |
| | ACS | 5 | 5 | 5 | 5 | 5 |

| | | | | | |
|---|---|---|---|---|---|
| Minimum developing time (sec) | 17 | 17 | 17 | 18 | 22 |
| Sensitivity (mJ/cm²) | 55 | 50 | 50 | 64 | 55 |
| Adhesiveness (μm) | 6 | 6 | 7 | 7 | 6 |
| Resolution (μm) | 9 | 10 | 9 | 10 | 15 |
| Storage stability | A | A | B | A | A |

### REFERENCE SIGNS LIST

1: photosensitive element, 2: support, 3, 13: photosensitive resin layer, 4: protective layer, 11: insulation layer, 12: conductor layer, 14: mask, 15: active light ray, 16: resist pattern, 17: wiring layer, 18: wiring board.

1. A photosensitive resin composition comprising: a binder polymer; a photopolymerizable compound; a photopolymerization initiator; and an anthracene-based sensitizer, wherein
the binder polymer comprises a polymer (a) having a hydroxyalkyl (meth)acrylate unit and a styrene or styrene derivative unit and having a content of the styrene or styrene derivative unit of 40% by mass or more.

2. The photosensitive resin composition according to claim 1, wherein the photopolymerizable compound comprises a polyfunctional monomer having two or more reactive groups reacting with radicals and having 2 to 40 of oxyethylene groups and/or oxypropylene groups in total.

3. The photosensitive resin composition according to claim 1, wherein the photopolymerizable compound comprises 2,2-bis(4-((meth)acryloxypolyethoxy)phenyl)propane in which the number of oxyethylene groups is 10 or more.

4. The photosensitive resin composition according to claim 1, wherein the photopolymerizable compound comprises 2,2-bis(4-((meth)acryloxypolyethoxy)phenyl)propane in which the number of oxyethylene groups is less than 10.

5. The photosensitive resin composition according to claim 1, wherein the photopolymerizable compound comprises 2,2-bis(4-((meth)acryloxypolyethoxy)phenyl)propane in which the number of oxyethylene groups is 10 or more and 2,2-bis(4-((meth)acryloxypolyethoxy)phenyl)propane in which the number of oxyethylene groups is less than 10.

6. The photosensitive resin composition according to claim 1, wherein a weight average molecular weight of the polymer (a) is 30000 to 40000.

7. The photosensitive resin composition according to claim 1, wherein a content of the anthracene-based sensitizer is 0.2 parts by mass or more and less than 0.8 parts by mass with respect to 100 parts by mass of the total amount of the binder polymer and the photopolymerizable compound.

8. A photosensitive element comprising: a support; and a photosensitive resin layer formed using the photosensitive resin composition according to claim 1 on the support.

9. A method for producing a wiring board, the method comprising:
a step of providing a photosensitive resin layer on a substrate by using the photosensitive resin composition according to claim 1;
a step of photo-curing a part of the photosensitive resin layer;
a step of removing an uncured area of the photosensitive resin layer to form a resist pattern; and
a step of forming a wiring layer on a part of the substrate in which the resist pattern is not formed.

10. A method for producing a wiring board, the method comprising:
a step of providing a photosensitive resin layer on a substrate by using the photosensitive element according to claim 8;
a step of photo-curing a part of the photosensitive resin layer;
a step of removing an uncured area of the photosensitive resin layer to form a resist pattern; and
a step of forming a wiring layer on a part of the substrate in which the resist pattern is not formed.
